(19) United States
(12) Patent Application Publication
(10) Pub. No.: US 2025/0081340 A1
(43) Pub. Date: Mar. 6, 2025

(54) PRINTED CIRCUIT BOARD

(71) Applicant: SAMSUNG ELECTRO-MECHANICS CO., LTD., Suwon-si (KR)

(72) Inventor: In Gun KIM, Suwon-si (KR)

(73) Assignee: SAMSUNG ELECTRO-MECHANICS CO., LTD., Suwon-si (KR)

(21) Appl. No.: 18/435,160

(22) Filed: Feb. 7, 2024

(30) Foreign Application Priority Data
Aug. 31, 2023 (KR) 10-2023-0115182

(51) Int. Cl. H05K 1/03; H05K 1/05; H05K 1/11

(52) U.S. Cl. CPC H05K 1/0306; H05K 1/115; H05K 1/053; H05K 2201/0989

(57) ABSTRACT

A printed circuit board includes a glass layer having a first region having first transmittance and a second region having second transmittance, different from the first transmittance, and a first wiring layer disposed on the glass layer.

### CROSS-REFERENCE TO RELATED APPLICATION(S)

This application claims benefit of priority to Korean Patent Application No. 10-2023-0115182 filed on Aug. 31, 2023 in the Korean Intellectual Property Office, the disclosure of which is incorporated herein by reference in its entirety.

### TECHNICAL FIELD

The present disclosure relates to printed circuit board.

Multichip packages including a memory chip such as a high bandwidth memory (HBM) and a processor chip such as a central processing unit (CPU), a graphics processing unit (GPU), an application specific integrated circuit (ASIC), or a field programmable gate array (FPGA) have been used to process data exponentially increasing due to recent developments in artificial intelligence (AI) technology.

Accordingly, attempts have been made to use glass materials. However, the transparency of glass materials has caused an issue during a process using light.

### SUMMARY

An aspect of the present disclosure provides a printed circuit board including a glass layer.

Another aspect of the present disclosure provides a printed circuit board in which no error occurs even when a process and an inspection using light are performed.

Another aspect of the present disclosure provides a printed circuit board having improved reliability.

According to an aspect of the present disclosure, there is provided a printed circuit board including a glass layer having a first region having first transmittance and a second region having second transmittance, different from the first transmittance, and a first wiring layer disposed on the glass layer.

According to another aspect of the present disclosure, there is provided a printed circuit board including a glass layer having a first region internally positioned and a second region externally positioned with respect to a stacking direction, and a first wiring layer disposed on the glass layer. Transmittance of the second region may be lower than transmittance of the first region.

According to example embodiments of the present disclosure, there may be provided a printed circuit board including a glass layer.

According to example embodiments of the present disclosure, there may be provided a printed circuit board in which no error occurs even when a process and an inspection using light are performed.

According to example embodiments of the present disclosure, there may be provided a printed circuit board having improved reliability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective view illustrating an example of an electronic device;

FIG. 3 is a schematic cross-sectional view illustrating an example of a printed circuit board;

FIG. 4 is a schematic cross-sectional view illustrating another example of a printed circuit board;

FIGS. 5A to 5I are schematic cross-sectional views illustrating an example of a method of manufacturing a printed circuit board; and

FIGS. 6A to 6I are schematic cross-sectional views illustrating an example of a method of manufacturing a printed circuit board.

### DETAILED DESCRIPTION

Hereinafter, the present disclosure will be described with reference to the accompanying drawings. The shapes and sizes of components in the drawings may be exaggerated or reduced for clearer description.

### Electronic Device

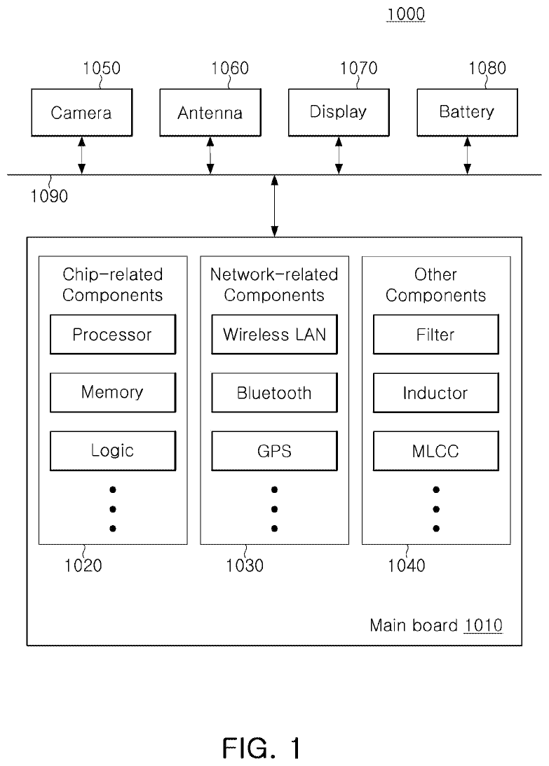

FIG. 1 is a schematic block diagram illustrating an example of an electronic device system.

Referring to FIG. 1, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an m analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

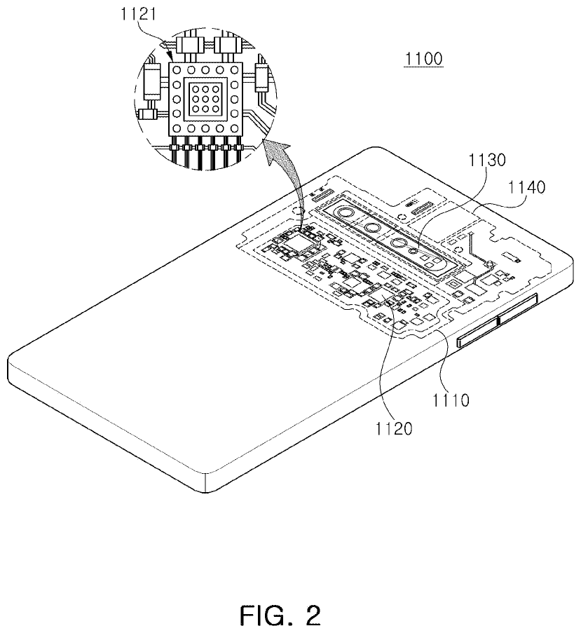

FIG. 2 is a schematic perspective view illustrating an example of an electronic device.

Referring to FIG. 2, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not necessarily limited to the smartphone 1100, and may be other electronic devices as described above.

### Printed Circuit Board

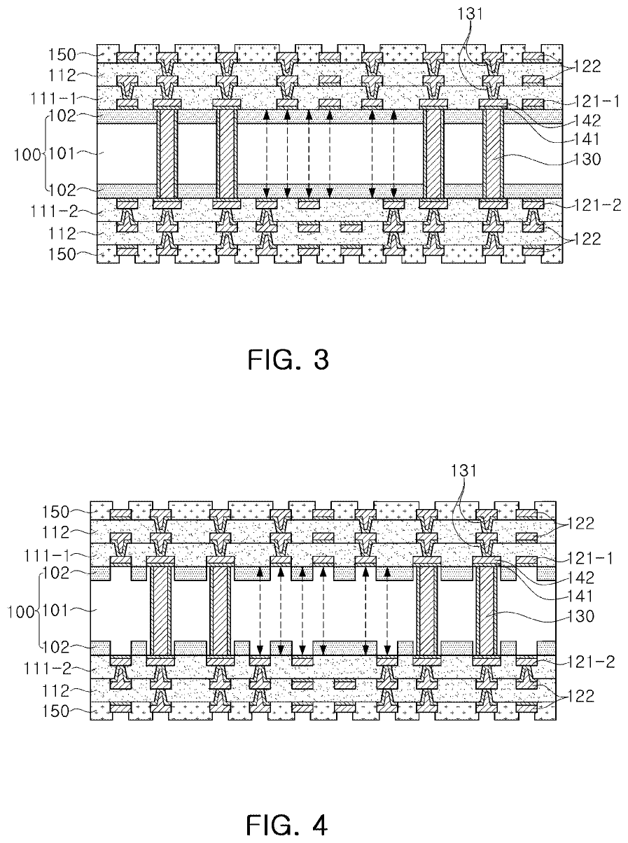

FIG. 3 is a schematic cross-sectional view illustrating an example of a printed circuit board.

Referring to FIG. 3, a printed circuit board according to an example may include a glass layer 100 having a first region 101 having first transmittance and a second region 102 having second transmittance different from the first transmittance, a first-first wiring layer 121-1 disposed on an upper surface of the glass layer 100, a first-first insulating layer 111-1 disposed on the upper surface of the glass layer 100 to cover the first-first wiring layer 121-1, a first-second wiring layer 121-2 disposed on a lower surface of the glass layer 100, and a first-second insulating layer 111-2 disposed on the lower surface of the glass layer 100 to cover the first-second wiring layer 121-2.

The printed circuit board according to an example including the glass layer 100 may basically have excellent flatness and may also have a low coefficient of thermal expansion (CTE), which may be advantageous in warpage control. In particular, the printed circuit board according to an example may include the glass layer 100 as a core layer, and thus may be advantageous in warpage control even in an operation of stacking other insulating layers. In addition, even when the first-first insulating layer 111-1, the first-second insulating layer 111-2, and a second insulating layer 112 are sequentially stacked on the glass layer 100, the flatness may be further improved. Therefore, it may be more advantageous in forming a high-density fine circuit having a fine pitch. In addition, the dielectric properties of the glass layer 100, such as glass having variable properties of Dk 2.5 to 11, may reduce the number of layers of the printed circuit board and further increase a degree of design freedom.

The printed circuit board according to an example may allow the glass layer 100 to have a first region 101 and a second region 102 having different transmittances, such that light from an upper side or a lower side of the glass layer 100 may not be transmitted through the glass layer 100. Specifically, with respect to a stacking direction of the printed circuit board, the inside of the glass layer 100 may be the first region 101, the outside of the glass layer 100 may be the second region 102, and the second transmittance of the second region 102 may be lower than the first transmittance of the first region 101. This may be a result of processing upper and lower sides of the glass layer 100 having only the first region 101 to form the second region 102 on each of the upper and lower sides of the glass layer 100. The second region 102 may have a microstructure different from that of the first region 101, and the first and second regions 101 and 102 may have different transmittances caused by a difference between the microstructures.

In FIG. 3, the second region 102 is illustrated as being formed with a certain boundary, but the present disclosure is not limited thereto. Depending on a degree of processing, the boundary may be a rough or unclear. A microstructure may be observed by photographing a cut cross-section of a printed circuit board with a scanning microscope, and a region having a structure different from that of an adjacent region may be distinguished and identified. The first region 101 and the second region 102 may be distinguished from each other by different transmittances thereof. The second region 102 may have transmittance lower than that of the first region 101, and may correspond to a region through which light may not pass. That is, a region having transmittance having a certain value or less may be referred to as the second region 102. In this case, the second transmittance of the second region 102 may preferably be 30% or less, but the present disclosure is not necessarily limited thereto. The first region 101 and the second region 102 may be distinguished from each other by the second transmittance being less than or equal to a certain percentage of the first transmittance.

The glass layer 100 may be divided into the first region 101 and the second region 102, and the second region 102 may not transmit light, such that there may be little influence on a wiring layer of an opposite side during an automated optical inspection (AOI). When the glass layer 100 has only the first region 101, light may be transmitted through the glass layer 100. Thus, when light for the AOI is irradiated from an upper side of the glass layer 100, a wiring layer disposed on a lower side of the glass layer 100 may be recognized, such that an error may be highly likely to occur. That is, when the AOI is performed on the upper side of the glass layer 100, it may be reasonable to inspect only the first-first wiring layer 121-1 disposed on the upper surface of the glass layer 100. However, the glass layer 100 may transmit light, and thus the first-second wiring layer 121-2 disposed on the lower surface of the glass layer 100 may be recognized, and may be recognized as a defect. That is, even when the first-first wiring layer 121-1 and the first-second wiring layer 121-2 are formed on different surfaces, an error may occur in which a wiring layer on a lower surface is detected in the AOI performed on the upper side. The same error may occur, even when the AOI is performed on the lower side. The AOI is only provided as an example. Even when an inspection and a process are performed using light, an error may occur when the glass layer 100 has only the first region 101. For example, even when an alignment mark is formed to align a wire pattern, the upper and lower marks may be mistaken for each other, and various errors may occur because the glass layer 100 is transparent. The printed circuit board according to an example may not be subject to such errors because the glass layer 100 has the second region 102, and the second region 102 does not transmit light or has a low transmittance. The same effect may be obtained even when the first insulating layer 111-1 or the first insulating layer 111-2 disposed on the glass layer 100 is transparent.

The glass layer 100 may include glass, an amorphous solid. Glass may include, for example, pure silicon dioxide (about 100% SiO₂), soda lime glass, borosilicate glass, alumino-silicate glass, and the like. However, the present disclosure is not limited thereto, and an alternative glass material such as fluorine glass, phosphate glass, chalcogen glass, or the like may also be used as a material for the glass layer 100. In addition, other additives may be further included to form glass with specific physical properties. Such additives may include calcium carbonate (for example, lime) and sodium carbonate (for example, soda), as well as magnesium, calcium, manganese, aluminum, lead, boron, iron, chromium, potassium, sulfur and antimony, and a carbonate and/or an oxide of such elements and other elements. The glass layer 100, a layer distinguished from a material including a glass fiber (or glass cloth or glass fabric), for example, a copper clad laminate (CCL), a prepreg (PPG), or the like, may be understood as, for example, plate glass. The glass layer 100 may be plate glass supported by a support such as another core or the like.

The second region 102 of the glass layer 100 may be disposed on each of the upper and lower surfaces of the glass layer 100, and may extend toward the inside of the glass layer 100. Such a configuration may be a result of performing processing on the upper and lower sides of the glass layer 100. Specifically, by irradiating a laser from the upper and lower sides of the glass layer 100, the second region 102 may be formed along the upper and lower surfaces of the glass layer 100 on which a through-via 130 is not formed. An ultrafast laser may be used as the laser, but the present disclosure is not necessarily limited thereto. The shorter an irradiation cycle of the laser, the more modification of the microstructure may occur. For example, a picosecond-scale laser may be more preferable than a nanosecond-scale laser, and a femtosecond-scale laser may be more preferable for modification of a microstructure of the glass layer 100. In this case, it may be preferable to modify the microstructure over a large area using a bar-shaped laser rather than a spot-shaped laser. When the bar-shaped laser is used, the second region 102 may be relatively uniformly formed, and a boundary between the first region 101 and the second region 102 may be relatively uniformly formed. However, a method of processing the second region 102 of the glass layer 100 is not necessarily limited to the above-described method, and may include a method of injecting different materials such as impurities into the upper and lower sides of the glass layer 100 to modify the microstructure, and the second region 102 may be formed through physical or chemical modification using other methods. That is, any method of modifying, by those skilled in the art, the microstructure of the glass layer 100 may be used without limitation.

In FIG. 3, the second region 102 is illustrated as being formed on the upper and lower surfaces of the glass layer 100, but the present disclosure is not necessarily limited thereto, and the second region 102 is formed on one surface, among the upper surface and the lower surface of the glass layer 100. Even when the second region 102 is formed one surface, among the upper surface and the lower surface of the glass layer 100, it may be sufficient when light from the upper side does not reach the lower side or light from the lower side does not reach the upper side.

A thickness of the first region 101 of the glass layer 100 may be greater than a thickness of the second region 102. The thickness of the first region 101 and the thickness the second region 102 may be measured by photographing a cut cross-section of the printed circuit board with a scanning microscope, and the thickness may be an average value of thicknesses measured at any five points. A boundary between the second region 102 and the first region 101 may not be flat and may be rough. Thus, a method of measuring a roughness may be used to set an interface between the first region 101 and the second region 102, without being limited to the above-described method. That is, according to a method of measuring a central line average roughness (Ra), an average position of the boundary between the first region 101 and the second region 102 may be measured to measure the thickness of the first region 101 and the thickness of the second region 102. Alternatively, according to a method of measuring a 10-point average roughness (Rz), the boundary of the first region 101 and the second region 102 may be set based on a deviation between five highest points and five lowest points relative to the average position to measure each of the thickness of the first region 101 and the thickness of the second region 102. The second region 102 may be formed by processing the glass layer 100 having the first region 101 and modifying the microstructure of the glass layer 100, and thus the second region 102 may be a region penetrated by a processing means, such as a laser. Accordingly, the thickness of the second region 102 may be less than the thickness of the first region 101.

The glass layer 100 of the printed circuit board according to an example may include colored glass. The glass layer 100 may be processed to have color by injecting impurities, but the present disclosure is not limited thereto, and the printed circuit board may also be manufactured using the colored glass layer 100. When the glass layer 100 is colored and a process using light is performed on the upper side, an error that may occur on the lower side may be controlled using polarization. That the glass layer 100 has color may mean that both the first region 101 and the second region 102 of the glass layer 100 has color, but the present disclosure is not limited thereto, and may mean processing the glass layer 100 such that only the second region 102 of the glass layer 100 has color.

The first-first insulating layer 111-1, the first-second insulating layer 111-2, and the second insulating layer 112 may be disposed on the upper and lower surfaces of the glass layer 100, respectively. The first-first insulating layer 111-1, the first-second insulating layer 111-2, and the second insulating layer 112 may include an organic insulating material, respectively. The organic insulating material may include a thermosetting resin such as an epoxy resin, a thermoplastic resin such as polyimide, or a material including an inorganic filler, an organic filler, and/or a glass fiber (or glass cloth or glass fabric), together with such resins. For example, the insulating material may be a non-photosensitive insulating material such as an Ajinomoto build-up film (ABF) or PPG, but the present disclosure is not limited thereto, and other polymer materials may be used. In addition, the insulating material may be a photosensitive insulating material such as a photo-imageable dielectric (PID). In addition, the insulating material may include an adhesive sheet such as a bonding sheet (BS).

The first-first insulating layer 111-1 and the first-second insulating layer 111-2 may include the same insulating material, and the second insulating layer 112 may also include the same insulating material. Specifically, the first-first insulating layer 111-1, the first-second insulating layer 111-2, and the second insulating layer 112 may preferably include an ABF, but the present disclosure is not limited thereto, and may include other organic insulating materials. In addition, the present disclosure is not limited thereto, and the first-first insulating layer 111-1, first-second insulating layer 111-2, and second insulating layer 112 may include different materials. As the first-first insulating layer 111-1 and the first-second insulating layer 111-2 are disposed on the upper and lower surfaces of the glass layer 100, at least a portion of the second region 102 of the glass layer 100 may be in contact with the first-first insulating layer 111-1 and/or the first-second insulating layer 111-2.

The first-first wiring layer 121-1, the first-second wiring layer 121-2, and the second wiring layer 122 may respectively include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. Each wiring layer may perform various functions depending on the design. For example, each wiring layer may include a signal pattern, a power pattern, a ground pattern, and the like. The patterns may have various forms such as lines, planes, and pads. The first-first wiring layer 121-1, the first-second wiring layer 121-2, and the second wiring layer 122 may include a first metal layer 141 and a second metal layer 142 disposed on the first metal layer 141. The first metal layer 141 may include an electroless plating layer (or chemical copper) or a sputtering layer, or may include both the electroless plating layer (or chemical copper) and the sputtering layer, as necessary. The second metal layer 142 may be formed of an electrolytic plating layer (or electroplated copper) using the first metal layer 141 as a seed layer, and may also be formed of metal foil (or copper foil).

At least a portion of the first-first wiring layer 121-1 and at least a portion of the first-second wiring layer 121-2 may be disposed to be misaligned with each other with respect to the glass layer 100. The first-first wiring layer 121-1 and the first-second wiring layer 121-2, disposed to be misaligned with each other, may mean that a region of the upper surface of the glass layer 100 in which the first-first wiring layer 121-1 is formed and a region of the lower surface of the glass layer 100 in which the first-second wiring layer 121-2 is formed do not correspond to each other or are not symmetrical to each other. That is, as indicated by the arrow of FIG. 3, with respect to a cross-sectional view of the printed circuit board, the first-first wiring layer 121-1 may not be formed on the upper surface of the glass layer 100, and there may be a region of the lower surface of the glass layer 100 in which the first-second wiring layer 121-2 is formed, or vice versa.

When the glass layer 100 does not have the second region 102, an occur may be likely to occur due to the first-second wiring layer 121-2 formed on the lower surface of the glass layer 100, not the first-first wiring layer 121-1 formed on the upper surface of the glass layer 100, during a process using light, performed on the upper side. In this case, when the first-first wiring layer 121-1 and the first-second wiring layer 121-2 are disposed to be symmetrical to each other with respect to the glass layer 100, such an error may not occur. However, the first-second wiring layer 121-1 and the first-second wiring layer 121-2 are disposed to be misaligned with each other with respect to the glass layer 100, such an inspection error may occur. In the printed circuit board according to an example, even when the first-first wiring layer 121-1 and the first-second wiring layer 121-2 are disposed to be misaligned with each other, such an error may not occur due to the glass layer 100 having the second region 102. That is, the glass layer 100 may have the second region 102 having the second transmittance, thereby increasing a degree of design freedom of the first-first wiring layer 121-1, disposed on the upper surface of the glass layer 100, and the first-second wiring layer 121-2, disposed on the lower surface of the glass layer 100.

The through-via 130, penetrating the glass layer 100, may include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The through-via 130 may penetrate the upper and lower surfaces of the glass layer 100. Upper and lower surfaces of the through-via 130 may be substantially coplanar with the upper and lower surfaces of the glass layer 100. In FIG. 3, the through-via 130 is illustrated as a filled via, passing through the upper and lower surfaces of the glass layer 100 and being filled with a metal layer, but the present disclosure is not limited thereto. The through-via 130 may be a conformal via, disposed along a wall surface of a via hole. A specific method of forming the through-via 130 is not limited thereto. The through-via 130 may perform various functions depending on the design. For example, the through-via 130 may include a ground via, a power via, a signal via, and the like. The through-via 130 may have a substantially circular shape, an elliptical shape, or a polygonal shape on a plane, but the present disclosure not limited thereto, and may have, for example, a complex shape in which various shapes are combined into one on a plane in terms of securing close contact by increasing a specific surface area. A side surface of the through-via 130 may be substantially perpendicular to the upper and lower surfaces of the through-via 130, but the present disclosure is not limited thereto, and may be tapered to have an hourglass shape in cross-section, as necessary.

The upper and lower surfaces of the through-via 130 may be covered by the first-first wiring layer 121-1 and the first-second wiring layer 121-2, respectively. Such a configuration may be a result of forming the through-via 130, performing a planarization process of the glass layer 100 such that the upper and lower surfaces of the through-via 130 are substantially coplanar with the upper and lower surfaces of the glass layer 100, respectively, and forming the first-first wiring layer 121-1 and the first-second wiring layer 121-2. That is, the first metal layer 141, functioning as a seed layer of the first-first wiring layer 121-1 and the first-second wiring layer 121-2, may be configured to cover each of the upper and lower surfaces of the through-via 130.

The printed circuit board according to an example may further include a first via layer 131 connecting the first-first wiring layer 121-1 and the second wiring layer 122 to each other, connecting the first-second wiring layer 121-2 and the second wiring layer 122 to each other, or connecting the second wiring layers 122 to each other. In this case, the first via layer 131 may penetrate at least a portion of the first-first insulating layer 111-1, at least a portion of the first-second insulating layer 111-2, or at least a portion of the second insulating layer 112.

The first via layer 131 may include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The first via layer 131 may include a filled via filling a via hole, but may also include a conformal via disposed along a wall surface of the via hole. The first via layer 131 may perform various functions depending on the design. For example, the first via layer 131 may include a ground via, a power via, a signal via, and the like. The first via layer 131 may include an electroless plating layer (or chemical copper) and an electrolytic plating layer (or electrolytic copper). The first via layer 131 may include a sputtering layer instead of the electroless plating layer (or chemical copper), or may include both the electroless plating layer (or chemical copper) and the sputtering layer, as necessary.

In the printed circuit board according to an example, one second insulating layer 112 is illustrated as being stacked on each of the first-first insulating layer 111-1 and the first-second insulating layer 111-2, but the present disclosure is not limited thereto, and the second insulating layer 112 may include a plurality of insulating layers, as necessary. That is, the second insulating layer 112 may be formed as one or more insulating layers. As a non-limiting example, the second insulating layer 112 may be disposed only on one insulating layer, among the first-first insulating layer 111-1 or the first-second insulating layer 111-2, and may have an asymmetrical structure. In the glass layer 100 having high rigidity, warpage may be less likely to occur, and thus an asymmetrical substrate may be implemented. As the second insulating layer 112 includes one or more insulating layers, the second wiring layer 122 may also include one or more wiring layers, and the first via layer 131, connecting the second wiring layers 122 to each other, may also include one or more via layers.

The printed circuit board according to an example may further include a solder resist layer 150, disposed on the second insulating layer 112. The solder resist layer 150 may be disposed on an outermost side of the printed circuit board to externally protect the printed circuit board. The solder resist layer 150 may use a known solder resist. The solder resist layer 150 may include a liquid or film-type solder resist, but the present disclosure is not limited thereto. Other types of insulating materials may be used, and a thermosetting resin and an inorganic filler dispersed in the thermosetting resin may be included, but a glass fiber may not be included. The insulating resin may be a photosensitive insulating resin, and the filler may be an inorganic filler and/or an organic filler, but the present disclosure is not limited thereto. Other polymer materials may be used, as necessary. The solder resist layer 150 may have an opening, and at least a portion of the second wiring layer 122 may be exposed through the opening. The second wiring layer 122, exposed through the opening, may be connected to a main board or another printed circuit board, and may also be connected to other devices such as a semiconductor chip. A surface treatment layer may be further formed on a pattern exposed through the opening, as necessary. Alternatively, a metal bump may be further formed on the pattern exposed through the opening.

The printed circuit board according to an example is not limited to the components illustrated in FIG. 3, and may further include a general component of a printed circuit board. That is, the printed circuit board may further include a component that could be used by those skilled in the art.

FIG. 4 is a schematic cross-sectional view illustrating another example of a printed circuit board.

Referring to FIG. 4, a printed circuit board according to another example may be different from the printed circuit board according to an example in terms of a second region 102 of a glass layer 100.

The second region 102 may be formed in at least a portion of upper and lower surfaces of the glass layer 100 in which a first-first wiring layer 121-1 and a first-second wiring layer 121-2 are not formed. Such a configuration may occur because an operation of processing the glass layer 100 to form the second region 102 is performed after an operation of forming the first-first wiring layer 121-1 and the first-second wiring layer 121-2. That is, with respect to the upper surface of the glass layer 100, when the first-first wiring layer 121-1 is formed and then a microstructure of the glass layer 100 is modified by performing laser processing on an upper side of the glass layer 100 to form the second region 102, the second region 102 may be formed along the upper surface of the glass layer 100 on which the first-first wiring layer 121-1 is not formed. With respect to the lower surface of the glass layer 100, the second region 102 may be formed along the lower surface of the glass layer 100 on which the first-second wiring layer 121-2 is not formed, for the same reason. That is, the second region 102 may be formed in a region excluding a region in which the first-first wiring layer 121-1 and the first-second wiring layer 121-2 are formed, and may be engraved. In this case, the second region 102 may be disposed in a region in which the first-first wiring layer 121-1 and the first-second wiring layer 121-2 are not formed, such that a portion of a first region 101 may be disposed to be in contact with the first-first wiring layer 121-1 and the first-second wiring layer 121-2.

In FIG. 4, the second region 102 is illustrated as being formed to be perpendicular along a boundary between the first-first wiring layer 121-1 and the first-second wiring layer 121-2, but the present disclosure is not limited thereto. A boundary between the first region 101 and the second region 102 may be expressed in various manners depending on a method of processing the glass layer 100. In particular, a change in the microstructure may not occur in a certain direction. In this case, a portion of the second region 102 may also penetrate lower portions of the first-first wiring layer 121-1 and the first-second wiring layer 121-2.

A configuration the same as that of the printed circuit board according to an example, among configurations other than the arrangement of the second region 102, may be applied to the printed circuit board according to another example, and thus repeated descriptions related thereto will be omitted.

### Method of Manufacturing Printed Circuit Board

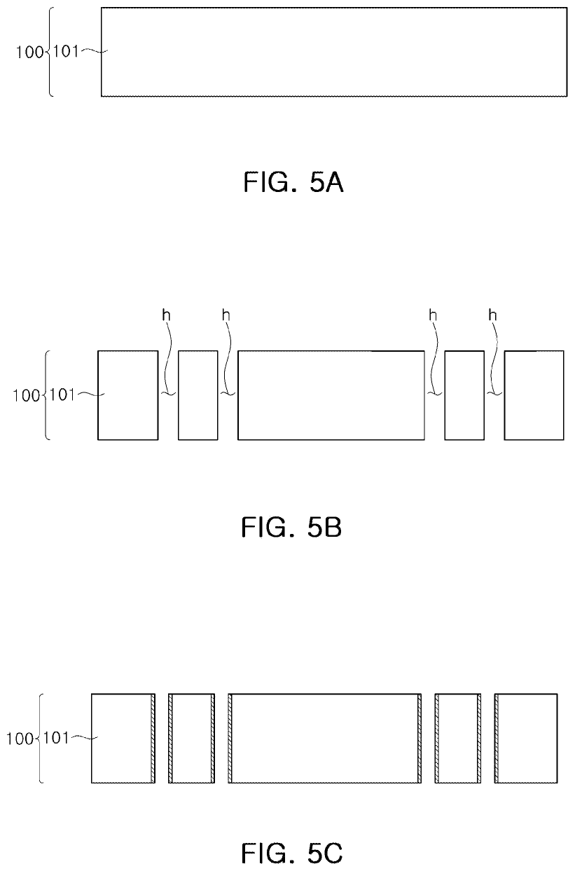

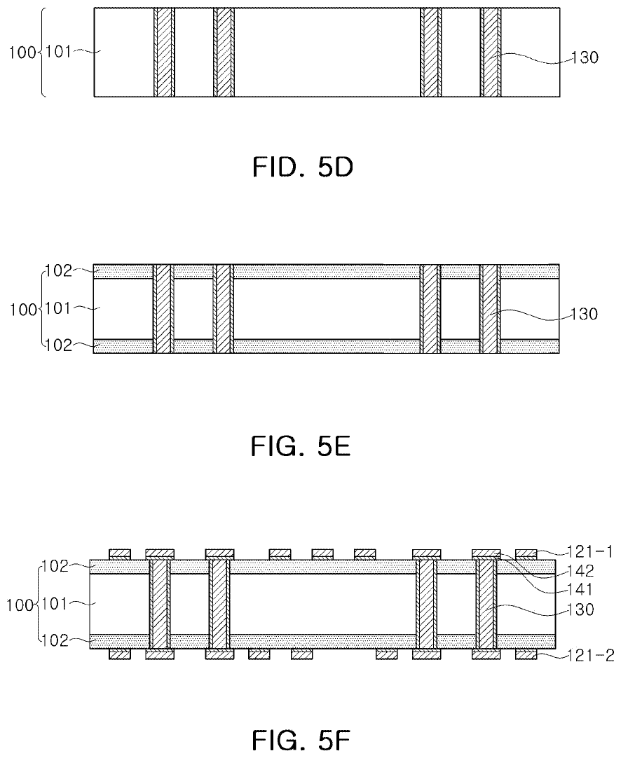

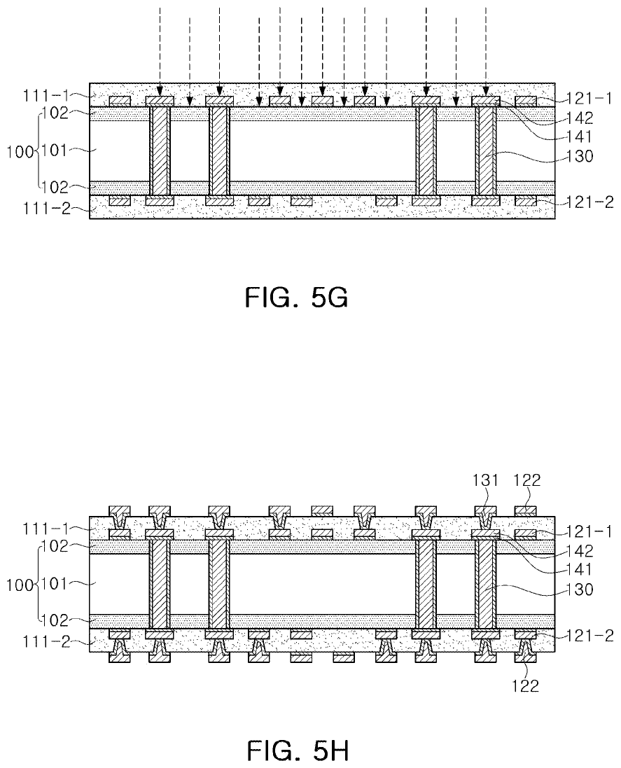

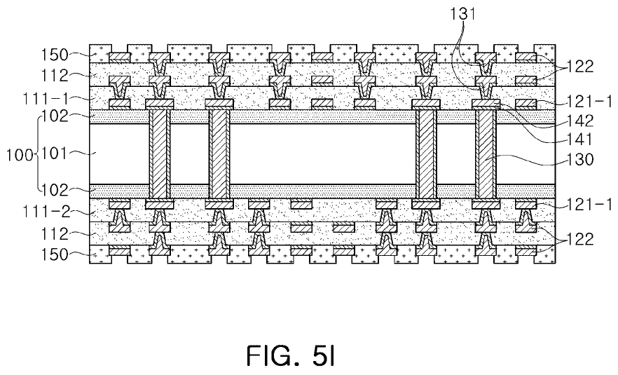

FIGS. 5A to 5I are schematic cross-sectional views illustrating an example of a method of manufacturing a printed circuit board.

Referring to FIG. 5A, a glass layer 100 may be prepared. The glass layer 100 may have only a first region 101, and may be in a state capable of transmitting light. The glass layer 100 may be in the form of a glass plate, or may be attached to another support means such as a core or jig.

Referring to FIGS. 5B to 5D, a through-via 130, penetrating upper and lower surfaces of the glass layer 100, may be formed. An operation of forming the through-via 130 in the glass layer 100 may include an operation of forming a through-hole h penetrating the glass layer 100, an operation of forming a metal layer on an inner wall of the through-hole h, and an operation of filling the through-hole h. The operation of forming the through-via 130 in the glass layer 100 may be performed using any known method of forming a through-glass via (TGV) without limitation.

In FIGS. 5B to 5D, the through-via 130 is illustrated as being formed only in the glass layer 100, but the present disclosure is not limited thereto. The through-via 130 may extend to the upper and lower surfaces of the glass layer 100. In this case, a final operation of forming the through-via 130 may further include an operation of planarizing the upper and lower surfaces of the glass layer 100, such that the upper and lower surfaces of the glass layer 100 may be substantially coplanar with upper and lower surfaces of the through-via 130, respectively, as illustrated in FIG. 5D. In this case, the planarization process may be, but is not limited to, chemical-mechanical polishing.

Referring to FIG. 5E, a second region 102 may be formed in the glass layer 100. An operation of forming the second region 102 may be performed by irradiating an ultrashort laser, but the present disclosure is not limited thereto. Any method capable of changing a microstructure of the glass layer 100 may be used without limitation, as described above in connection with the printed circuit board.

Referring to FIGS. 5F to 5G, an operation of forming a first-first insulating layer 111-1 and a first-second insulating layer 111-2 after forming a first-first wiring layer 121-1 and a first-second wiring layer 121-2 on the glass layer 100 may be included. The first-first wiring layer 121-1 and the first-second wiring layer 121-2 may be formed using separate processes, or may be collectively formed in a single process. The first-first wiring layer 121-1 and the first-second wiring layer 121-2 may be formed through an operation of forming a first metal layer 141 and an operation of forming a second metal layer 142 on the first metal layer 141, respectively. In this case, referring to FIG. 5G, an AOI inspection may be performed. In FIG. 5G, the AOI inspection is illustrated as being performed on an upper side of the glass layer 100, but the present disclosure is not necessarily limited to, and the inspection may be performed on a lower side of the glass layer 100. However, the present disclosure is not limited thereto, and the AOI inspection may also be performed in the operation of FIG. 5F, a previous operation of the operation of FIG. 5G. After the second region 102 of the glass layer 100 is formed, light from the upper side may not be transmitted through the glass layer 100. Thus, even when the inspection is performed, an error may be less likely to occur.

Referring to FIG. 5H, a second wiring layer 122 may be formed on the first-first insulating layer 111-1 and the first-second insulating layer 111-2, and a first via layer 131, connecting the second wiring layer 122 to the first-first wiring layer 121-1 or the first-second wiring layer 121-2, may be formed. The first via layer 131 and the second wiring layer 122 may be formed through an operation of forming a via hole penetrating at least a portion of the first-first insulating layer 111-1 or the first-second insulating layer 111-2, and then forming a first metal layer 141 and a second metal layer 142, but the present disclosure is not necessarily limited thereto. In an operation of forming the second wiring layer 122, an alignment mark may be detected to align a position in which the second wiring layer 122 is to be formed. In this case, there may be no influence of an opposite side due to the second region 102 of the glass layer 100.

Referring to FIG. 5I, a second insulating layer 112, a second wiring layer 122, and a first via layer 131 may be further formed, and a solder resist layer 150 may be formed on the second insulating layer 112.

A method of manufacturing the printed circuit board according to an example is not necessarily limited to the above-described method. As the printed circuit board according to an example may further include other components, and thus an addition or change may also be partially applied to the manufacturing method.

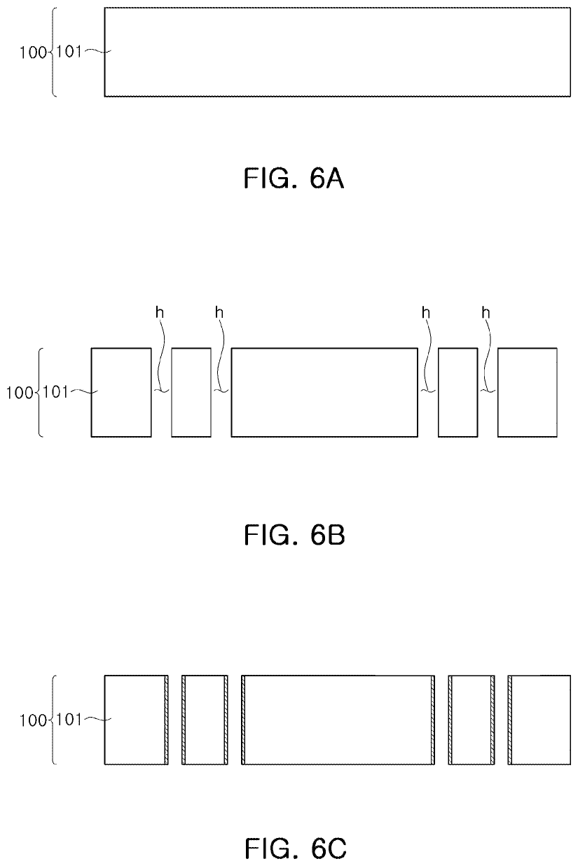

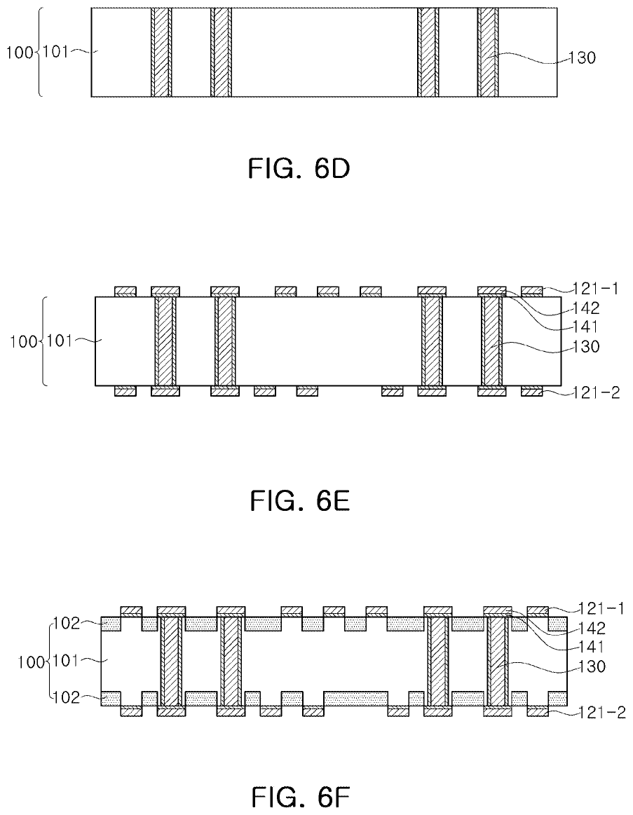

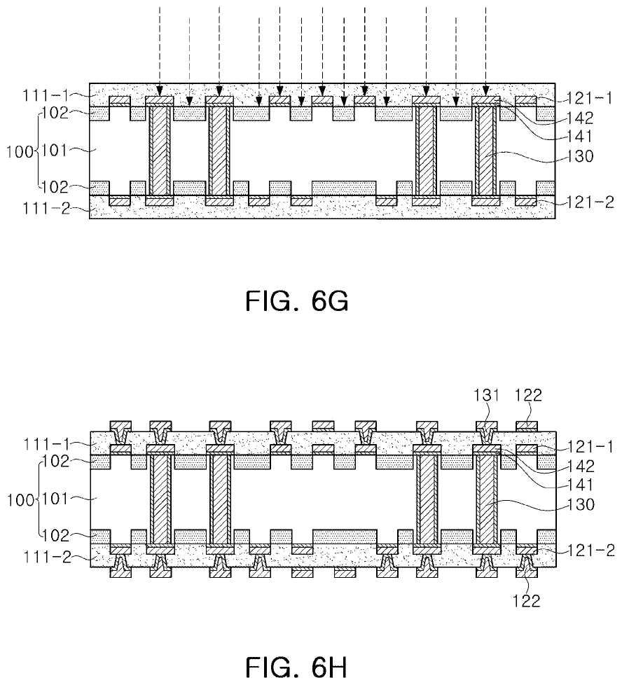

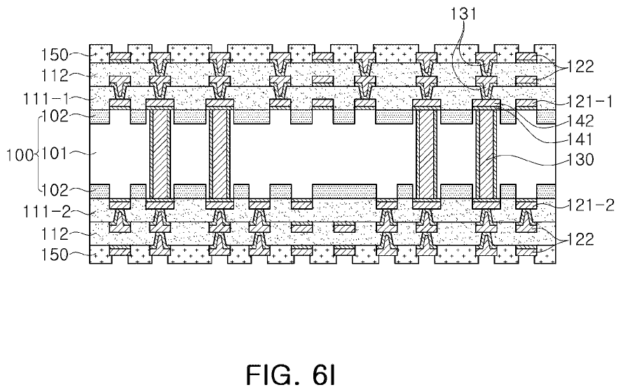

FIGS. 6A to 6I are schematic cross-sectional views illustrating an example of a method of manufacturing a printed circuit board. The operations shown in FIGS. 6A-6D and 6G-6I may correspond to those shown in FIGS. 5A-5D and 5G-5I. To avoid redundancy, the descriptions for FIGS. 6A-6D and 6G-6I are omitted here and may be referred to those for FIGS. 5A-5D and 5G-5I.

Referring to FIGS. 6E to 6F, a first-first wiring layer 121-1 and the first-second wiring layer 121-2 may be respectively formed on a glass layer 100, and then a second region 102 of the glass layer 100 may be formed. A method of forming the first-first wiring layer 121-1 and the first-second wiring layer 121-2 and a method of forming the second region 102 may be the same as the operations of the method of manufacturing the printed circuit board according to an example. Thus, repeated descriptions will be omitted.

In a method of manufacturing the printed circuit board according to another example, the second region 102 may be formed in the glass layer 100, after the first-first wiring layer 121-1 and the first-second wiring layer 121-2 are respectively formed. Thus, the second region 102 may be formed in a region in which the first-first wiring layer 121-1 and the first-second wiring layer 121-2 are not formed.

Among methods for manufacturing the printed circuit board according to another example, descriptions other than descriptions of the operations of forming the first-first wiring layer 121-1, the first-second wiring layer 121-2, and the second region 102 may be the same as descriptions of the method of manufacturing the printed circuit board according to an example, and thus repeated descriptions related thereto will be omitted.

As used herein, the terms “cover,” “to cover,” and “covering” may include entirely covering as well as at least partially covering, and may include directly covering as well as indirectly covering. In addition, the terms “fill,” to fill,” and “filling” may include not only completely filling, but also approximately filling, for example, may include a case in which some voids, pores or the like are present.

As used herein, a process error or a positional deviation occurring in a manufacturing process, an error in measurement, and the like may be included. For example, “substantially perpendicular” may include not only “completely perpendicular,” but also “approximately perpendicular.” In addition, “substantially coplanar” may include not only “completely coplanar,” but also “approximately coplanar.”

As used herein, the same insulating material may mean not only the exact same insulating material, but also the same type of insulating material. Thus, compositions of insulating materials may be substantially the same, but specific composition ratios thereof may slightly vary.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a glass layer having a first region having first transmittance and a second region having second transmittance, different from the first transmittance; and
a first wiring layer disposed on the glass layer.

2. The printed circuit board of claim 1, wherein
the second region is positioned on each of an upper side and a lower side of the glass layer, and
at least a portion of the first region is positioned on a central side between the upper side and the lower side of the glass layer.

3. The printed circuit board of claim 2, wherein the second transmittance is lower than the first transmittance.

4. The printed circuit board of claim 2, wherein a thickness of the first region is greater than a thickness of the second region.

5. The printed circuit board of claim 1, wherein
the first wiring layer includes a first-first wiring layer disposed on an upper surface of the glass layer, and a first-second wiring layer disposed on a lower surface of the glass layer, and
at least a portion of the first-first wiring layer is disposed to be misaligned with at least a portion of the first-second wiring layer.

6. The printed circuit board of claim 1, wherein the second region is disposed in at least a portion of the glass layer in which the first wiring layer is not disposed.

7. The printed circuit board of claim 1, wherein the second region is disposed in at least a portion of the glass layer in which the first wiring layer is disposed.

8. The printed circuit board of claim 1, wherein the glass layer includes colored glass.

9. The printed circuit board of claim 1, further comprising:
a through-via penetrating the glass layer to connect the first wiring layer,
the first wiring layer includes a first metal layer and a second metal layer disposed on the first metal layer, and
the first metal layer of the first wiring layer covers each of an upper surface and a lower surface of the through-via.

10. The printed circuit board of claim 9, further comprising:
a first insulating layer disposed on the glass layer, and covering the first wiring layer;
one or more second insulating layers disposed on the first insulating layer; and
one or more second wiring layers disposed on or within the one or more second insulating layers.

11. The printed circuit board of claim 10, further comprising:
a solder resist layer disposed on the second insulating layer, and having an opening exposing at least a portion of the second wiring layer.

12. A printed circuit board comprising:
a glass layer having a first region internally positioned and a second region externally positioned with respect to a stacking direction; and
a first wiring layer disposed on the glass layer,
wherein transmittance of the second region is lower than transmittance of the first region.

13. The printed circuit board of claim 12, further comprising:
a first insulating layer disposed on the glass layer, and covering the first wiring layer,
wherein at least a portion of the second region is in contact with the first insulating layer.

14. The printed circuit board of claim 12, wherein a portion of the first region is in contact with the first wiring layer.

15. The printed circuit board of claim 12, wherein the first region is spaced apart from the first wiring layer.

16. The printed circuit board of claim 12, wherein a thickness of the first region is greater than a thickness of the second region.

17. The printed circuit board of claim 12, wherein the second region is positioned on at least a portion of each of an upper surface and a lower surface of the glass layer, and extends to the inside of the glass layer.
